(19) United States
(12) Patent Application Publication
(10) Pub. No.: US 2025/0202446 A1
(43) Pub. Date: Jun. 19, 2025

(54) DIFFERENTIAL AMPLIFIER

(71) Applicant: Asahi Kasei Microdevices Corporation, Tokyo (JP)

(72) Inventors: Daisuke MATSUOKA, Tokyo (JP); Yuki HORI, Tokyo (JP)

(21) Appl. No.: 18/970,858

(22) Filed: Dec. 5, 2024

(30) Foreign Application Priority Data
Dec. 13, 2023 (JP) 2023-209756

(51) Int. Cl. H03F 3/45

(52) U.S. Cl. CPC H03F 3/45475; H03F 2200/03; H03F 2200/141; H03F 2200/168

(57) ABSTRACT

Provided is a differential amplifier comprising: a first differential amplification circuit that has a first input terminal, a second input terminal, a first output terminal and a second output terminal which respectively output a first output signal and a second output signal; an RC filter that filters the first output signal and the second output signal and outputs them; a second differential amplification circuit that has a third input terminal and a fourth input terminal to which the first output signal and the second output signal filtered by the RC filter are respectively input and a third output terminal which outputs a third output signal; and a third amplification circuit that has a fifth input terminal to which the third output signal is input and a fourth output terminal which outputs a fourth output signal according to the third output signal.

The contents of the following patent application(s) are incorporated herein by reference: NO. 2023-209756 filed in JP on Dec. 13, 2023

### BACKGROUND

### 1. Technical Field

The present invention relates to a differential amplifier.

### 2. Related Art

It is desirable for an amplifier that processes analog signals in an audio band at a high precision to have a high gain in the audio band, and such an amplifier includes two-pole compensation differential amplifiers (for example, refer to Patent Document 1) and the nested Miller compensation three-stage differential amplifiers (for example, refer to Non-Patent Document 1) which have even higher gain.

### PRIOR ART DOCUMENTS

### Patent Document

Patent document 1: Japanese Unexamined Patent Application, Publication No. Sho 61-230414

### Non-Patent Documents

Non-Patent Document 1: IEEE TRANSACTIONS ON SOLID-STATE CIRCUITS, VOL. 35, NO. 2, February 2000

### BRIEF DESCRIPTION OF THE DRAWINGS

FIG. 1 shows a first exemplary configuration of a differential amplifier 10 of the present embodiment.

FIG. 2 shows a first circuit example of an RC filter 30 in the differential amplifier 10 of the present embodiment.

FIG. 3 shows an equivalent circuit of a part of the differential amplifier 10 of the present embodiment.

FIG. 4 illustrates a gain and a phase characteristic in an open-loop of the differential amplifier 10 of the present embodiment.

FIG. 5 shows a second circuit example of the RC filter 30 in the differential amplifier 10 of the present embodiment.

FIG. 6 shows a third circuit example of the RC filter 30 in the differential amplifier 10 of the present embodiment.

FIG. 7 shows an equivalent circuit of a part of the differential amplifier 10 provided with the RC filter 30 of the third circuit example.

FIG. 8 shows a fourth circuit example of the RC filter 30 in the differential amplifier 10 of the present embodiment.

FIG. 9 shows a fifth circuit example of the RC filter 30 in the differential amplifier 10 of the present embodiment.

FIG. 10 shows a sixth circuit example of the RC filter 30 in the differential amplifier 10 of the present embodiment.

FIG. 11 shows a seventh circuit example of the RC filter 30 in the differential amplifier 10 of the present embodiment.

FIG. 12 shows an eighth circuit example of the RC filter 30 in the differential amplifier 10 of the present embodiment.

FIG. 13 shows a ninth circuit example of the RC filter 30 in the differential amplifier 10 of the present embodiment.

FIG. 14 shows an equivalent circuit of a part of the differential amplifier 10 provided with the RC filter 30 of the ninth circuit example.

FIG. 15 shows a tenth circuit example of the RC filter 30 in the differential amplifier 10 of the present embodiment.

FIG. 16 shows a second exemplary configuration of the differential amplifier 10 of the present embodiment.

FIG. 17 shows a differential amplifier 110 of a reference example.

FIG. 18 shows an equivalent circuit of a part of the differential amplifier 110 of the reference example.

FIG. 19 illustrates a gain and a phase characteristic in an open-loop of the differential amplifier 110 of the reference example.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

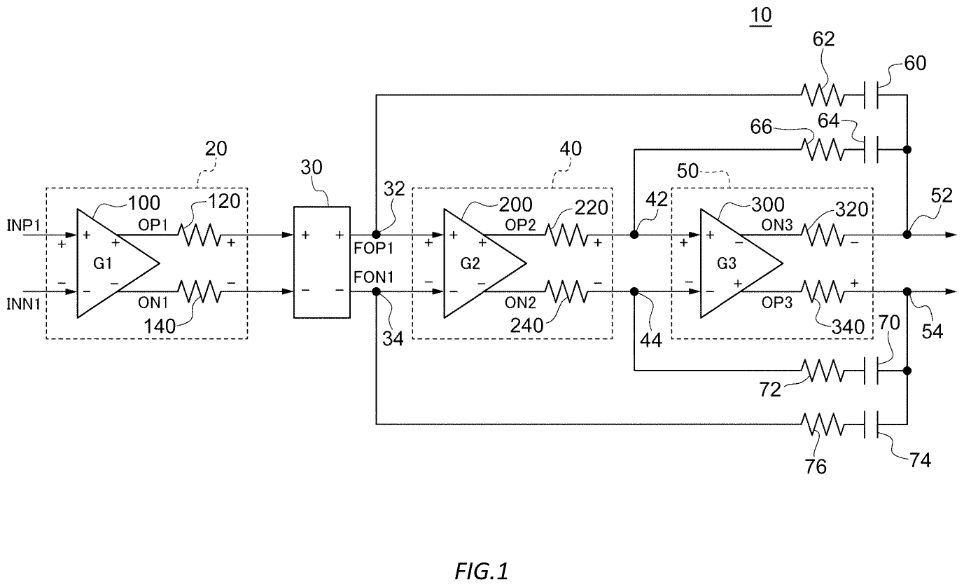

FIG. 1 shows a first exemplary configuration of a differential amplifier 10 of the present embodiment. For example, the differential amplifier 10 amplifies a signal level of a differentially input signal in the audio band to differentially output it. As an example, the differential amplifier 10 is a nested Miller compensation three-stage differential amplifier of a fully differential input-output type with an embedded two-pole compensation circuit. The differential amplifier 10 includes a first stage amplification circuit 20, an RC filter 30, a second stage amplification circuit 40, a third stage amplification circuit 50, a first feedback capacitor 60, a first feedback resistor 62, a second feedback capacitor 64, a second feedback resistor 66, a third feedback capacitor 74, a third feedback resistor 76, a fourth feedback capacitor 70, and a fourth feedback resistor 72.

The first stage amplification circuit 20 performs an amplifying operation of a first tier in the differential amplifier 10. The first stage amplification circuit 20 includes a first differential amplification circuit 100, a first output resistor 120, and a second output resistor 140.

A first input signal INP1 and a second input signal INN1 having the same signal level (voltage) but phase-inverted with each other are input to the first differential amplification circuit 100, and the first differential amplification circuit 100 amplifies a difference in signal levels between the first input signal INP1 and the second input signal INN1 that are input and outputs a first output signal OP1 and a second output signal ON1.

The first differential amplification circuit 100 includes a first input terminal to which the first input signal INP1 is input, a second input terminal to which the second input signal INN1 is input, and a first output terminal and a second output terminal which respectively output the first output signal OP1 and the second output signal ON1 according to the first input signal INP1 and the second input signal INN1. In the present example of FIG. 1, the first input terminal is a positive input terminal (+), the second input terminal is a negative input terminal (−), the first output terminal is a positive output terminal (+), and the second output terminal is a negative output terminal (−). The first differential amplification circuit 100 amplifies a difference between the voltages applied on the first input terminal and the second input terminal with a predetermined gain (amplification factor) G1 and generates an amplified voltage difference between the first output terminal and the second output terminal.

The first output resistor 120 has one end thereof connected to the first output terminal of the first differential amplification circuit 100. The second output resistor 140 has one end thereof connected to the second output terminal of the first differential amplification circuit 100. The first output resistor 120 and the second output resistor 140 are output impedances in the first stage amplification circuit 20. The first output resistor 120 and the second output resistor 140 may have the same resistance value.

The RC filter 30 has a positive input terminal thereof connected to another end of the first output resistor 120 and a negative input terminal thereof connected to another end of the second output resistor 140. The RC filter 30 is arranged between the first stage amplification circuit 20 and the second stage amplification circuit 40, and filters the first output signal OP1 and the second output signal ON1 output from the first output terminal and the second output terminal of the first differential amplification circuit 100 to output filtered signals FOP1, FON1. As an example, the RC filter 30 is a low-pass filter. In the RC filter 30, the attenuation amount of the first output signal OP1 and the second output signal ON1 varies according to the frequency of the first output signal OP1 and the second output signal ON1 output by the first differential amplification circuit 100. For example, in the RC filter 30, the larger the frequency of the first output signal OP1 and the second output signal ON1, the larger the attenuation amount of the first output signal OP1 and the second output signal ON1 becomes in a predetermined frequency range.

The second stage amplification circuit 40 performs an amplifying operation of a second tier in the differential amplifier 10. The second stage amplification circuit 40 includes a second differential amplification circuit 200, a third output resistor 220, and a fourth output resistor 240.

The second differential amplification circuit 200 is connected to a positive output terminal (+) and a negative output terminal (−) of the RC filter 30. The second differential amplification circuit 200 includes a third input terminal and a fourth input terminal to which the first output signal OP1 and the second output signal ON1 filtered by the RC filter 30 are respectively input, and a third output terminal which outputs third output signals OP2, ON2 according to the first output signal OP1 and the second output signal ON1. The third output terminal of the second differential amplification circuit 200 in the present example includes a positive third output terminal (+) and a negative third output terminal (−) which respectively output a third non-inverted output signal OP2 and a third inverted output signal ON2 according to the first output signal OP1 and the second output signal ON1. The second differential amplification circuit 200 amplifies, with a predetermined gain G2, a voltage difference between the third input terminal and the fourth input terminal resulting from the first output signal OP1 and the second output signal ON1 differentially input and generates an amplified voltage difference between the positive third output terminal and the negative third output terminal.

The third output resistor 220 has one end thereof connected to the positive third output terminal of the second differential amplification circuit 200. The fourth output resistor 240 has one end thereof connected to the negative third output terminal of the second differential amplification circuit 200. The third output resistor 220 and the fourth output resistor 240 are output impedances in the second stage amplification circuit 40. The third output resistor 220 and the fourth output resistor 240 may have the same resistance value.

The third stage amplification circuit 50 performs an amplifying operation of a third tier in the differential amplifier 10. The third stage amplification circuit 50 includes a third amplification circuit 300, a fifth output resistor 320, and a sixth output resistor 340.

The third amplification circuit 300 is connected to the positive third output terminal and the negative third output terminal of the second differential amplification circuit 200. The third amplification circuit 300 includes a fifth input terminal to which the third output signals OP2, ON2 output from the second differential amplification circuit 200 are input, and a fourth output terminal which outputs fourth output signals OP3, ON3 according to the third output signals OP2, ON2. The third amplification circuit 300 in the present example performs differential amplification. The fifth input terminal of the third amplification circuit 300 includes a positive fifth input terminal (+) to which the third non-inverted output signal OP2 is input and a negative fifth input terminal (−) to which the third inverted output signal ON2 is input. The fourth output terminal of the third amplification circuit 300 includes a negative fourth output terminal (−) and a positive fourth output terminal (+) which respectively output a fourth inverted output signal ON3 and a fourth non-inverted output signal OP3 according to the third non-inverted output signal OP2 and the third inverted output signal ON2. The third amplification circuit 300 amplifies, with a predetermined gain G3, a voltage difference between the positive fifth input terminal and the negative fifth input terminal resulting from the third non-inverted output signal OP2 and the third inverted output signal ON2 input and generates an amplified voltage difference between the negative fourth output terminal and the positive fourth output terminal.

The fifth output resistor 320 has one end thereof connected to the negative fourth output terminal of the third amplification circuit 300 and another end thereof connected to a negative output terminal of the differential amplifier 10. The sixth output resistor 340 has one end thereof connected to the positive fourth output terminal of the third amplification circuit 300 and another end thereof connected to a positive output terminal of the differential amplifier 10. The fifth output resistor 320 and the sixth output resistor 340 are output impedances in the third stage amplification circuit 50. The fifth output resistor 320 and the sixth output resistor 340 may have the same resistance value.

The first feedback capacitor 60 has one end thereof connected, via a first feedback resistor 62, to a node 32 between the positive output terminal of the RC filter 30 and the third input terminal of the second differential amplification circuit 200 and another end thereof connected to the negative fourth output terminal of the third amplification circuit 300 at a node 52. The first feedback capacitor 60 has a phase compensation capacitance. The first feedback resistor 62 has one end thereof connected to a node 32 between the positive output terminal of the RC filter 30 and the third input terminal of the second differential amplification circuit 200 and another end thereof connected to one end of the first feedback capacitor 60. The first feedback resistor 62 adjusts a phase characteristic of the differential amplifier 10. The first feedback capacitor 60 and the first feedback resistor 62 connected in series constitute a phase compensation circuit arranged in a feedback path from the negative output of the third amplification circuit 300 to the positive input of the second differential amplification circuit 200 in the differential amplifier 10.

The second feedback capacitor 64 has one end thereof connected, via a second feedback resistor 66, to a node 42 between the positive third output terminal of the second differential amplification circuit 200 and the positive fifth input terminal of the third amplification circuit 300 and another end thereof connected to the negative fourth output terminal of the third amplification circuit 300 at a node 52. The second feedback capacitor 64 has a phase compensation capacitance. The second feedback resistor 66 has one end thereof connected to a node 42 between the positive third output terminal of the second differential amplification circuit 200 and the positive fifth input terminal of the third amplification circuit 300 and another end thereof connected to one end of the second feedback capacitor 64. The second feedback resistor 66 adjusts the phase characteristic of the differential amplifier 10. The second feedback capacitor 64 and the second feedback resistor 66 connected in series constitute a phase compensation circuit arranged in a feedback path from the negative output of the third amplification circuit 300 to the positive input of the third amplification circuit 300 in the differential amplifier 10.

The third feedback capacitor 74 has one end thereof connected, via a third feedback resistor 76, to a node 34 between the negative output terminal of the RC filter 30 and the fourth input terminal of the second differential amplification circuit 200 and another end thereof connected to the positive fourth output terminal of the third amplification circuit 300. The third feedback capacitor 74 has a phase compensation capacitance. The third feedback resistor 76 has one end thereof connected to a node 34 between the negative output terminal of the RC filter 30 and the fourth input terminal of the second differential amplification circuit 200 and another end thereof connected to one end of the third feedback capacitor 74. The third feedback resistor 76 adjusts the phase characteristic of the differential amplifier 10. The third feedback capacitor 74 and the third feedback resistor 76 connected in series constitute a phase compensation circuit arranged in a feedback path from the positive output of the third amplification circuit 300 to the negative input of the second differential amplification circuit 200 in the differential amplifier 10.

The fourth feedback capacitor 70 has one end thereof connected, via a fourth feedback resistor 72, to a node 44 between the negative third output terminal of the second differential amplification circuit 200 and the negative fifth input terminal of the third amplification circuit 300 and another end thereof connected to the positive fourth output terminal of the third amplification circuit 300. The fourth feedback capacitor 70 has a phase compensation capacitance. The fourth feedback resistor 72 has one end thereof connected to a node 44 between the negative third output terminal of the second differential amplification circuit 200 and the negative fifth input terminal of the third amplification circuit 300 and another end thereof connected to one end of the fourth feedback capacitor 70. The fourth feedback resistor 72 adjusts the phase characteristic of the differential amplifier 10. The fourth feedback capacitor 70 and the fourth feedback resistor 72 connected in series constitute a phase compensation circuit arranged in a feedback path from the positive output of the third amplification circuit 300 to the negative input of the third amplification circuit 300 in the differential amplifier 10.

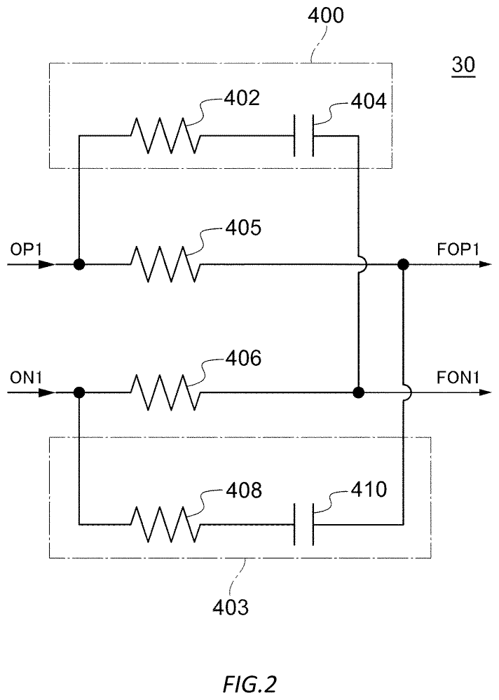

FIG. 2 shows a first circuit example of the RC filter 30 in the differential amplifier 10 of the present embodiment. The RC filter 30 may include a filter section which includes a filter capacitor and a filter resistor connected in series. The filter section may be connected between the first differential amplification circuit 100 and the second differential amplification circuit 200 so as not to be in a parallel connection relationship with the first feedback capacitor 60 and the second feedback capacitor 64. The RC filter 30 of the first circuit example includes a first filter section 400, a second filter section 403, a third filter resistor 405, and a fourth filter resistor 406.

The first filter section 400 has one end thereof connected to a node between the first output terminal of the first differential amplification circuit 100 and the third input terminal of the second differential amplification circuit 200 and another end thereof connected to a node between the second output terminal of the first differential amplification circuit 100 and the fourth input terminal of the second differential amplification circuit 200. The first filter section 400 includes a first filter resistor 402 and a first filter capacitor 404 connected in series. The first filter resistor 402 has one end thereof connected to the node between the first output terminal of the first differential amplification circuit 100 and the third input terminal of the second differential amplification circuit 200 and another end thereof connected to one end of the first filter capacitor 404. The first filter capacitor 404 has another end thereof connected to a node between the second output terminal of the first differential amplification circuit 100 and the fourth input terminal of the second differential amplification circuit 200.

The second filter section 403 has one end thereof connected between the second output terminal of the first differential amplification circuit 100 and the node to which the another end of the first filter section 400 is connected and another end thereof connected between the node to which the one end of the first filter section 400 is connected and the third input terminal of the second differential amplification circuit 200. The second filter section 403 includes a second filter resistor 408 and a second filter capacitor 410 connected in series. The second filter resistor 408 has one end thereof connected between the second output terminal of the first differential amplification circuit 100 and the node to which the another end of the first filter capacitor 404 is connected and another end thereof connected to one end of the second filter capacitor 410. The second filter resistor 408 may have the same resistance value as the first filter resistor 402. The second filter capacitor 410 has another end thereof connected between the node to which the one end of the first filter resistor 402 is connected and the third input terminal of the second differential amplification circuit 200.

The third filter resistor 405 is connected between the first output terminal of the first differential amplification circuit 100 and the third input terminal of the second differential amplification circuit 200, and in the present embodiment, it is connected between the node to which the one end of the first filter resistor 402 is connected and the node to which the another end of the second filter capacitor 410 is connected. The third filter resistor 405 may have a resistance value smaller than that of the first filter resistor 402. The fourth filter resistor 406 is connected between the second output terminal of the first differential amplification circuit 100 and the fourth input terminal of the second differential amplification circuit 200, and in the present embodiment, it is connected between the node to which the one end of the second filter resistor 408 is connected and the node to which the another end of the first filter capacitor 404 is connected. The fourth filter resistor 406 may have a resistance value smaller than that of the second filter resistor 408 and may have a resistance value that is the same as that of the third filter resistor 405.

The differential amplifier 10 of the present embodiment has the RC filter 30 arranged between the output of the first stage amplification circuit 20 and the input of the second stage amplification circuit 40 to generate a first pole, a second pole, and a zero point in an open-loop characteristic of the gain, allowing a stable operation of the differential amplifier 10.

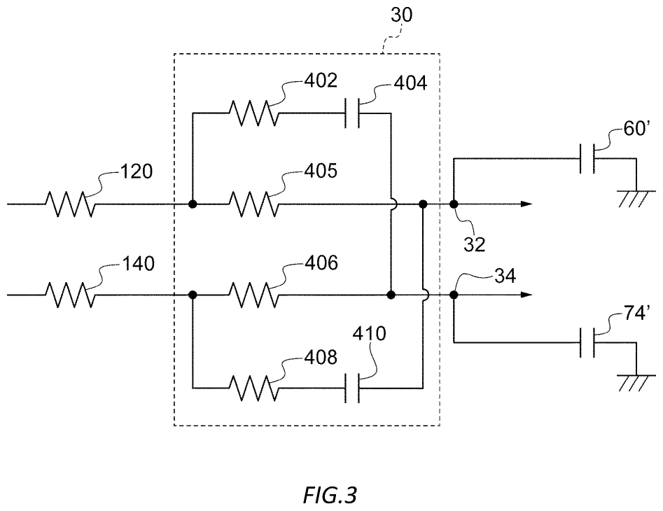

FIG. 3 shows an equivalent circuit of a part of the differential amplifier 10 of the present embodiment. FIG. 3 shows, as the equivalent circuit, a transmission circuit where the signal amplified by G1 times in the first stage amplification circuit 20 is input to the second stage amplification circuit 40 via the RC filter 30. In the equivalent circuit shown in FIG. 3, omission of some elements or resizing of elements has been equivalently performed and change of wiring has also been equivalently performed on the transmission circuit of the differential amplifier 10. Note that, in FIG. 3, the first feedback resistor 62 and the third feedback resistor 76 are omitted because they are elements to adjust the phase characteristic of the differential amplifier 10 and also elements that do not contribute to the first pole, the second pole, and the zero point.

The first feedback capacitor 60 has one end thereof connected to the output of the third stage amplification circuit 50 and another end thereof connected to the input of the second stage amplification circuit 40 via the first feedback resistor 62. Accordingly, the first feedback capacitor 60 can be regarded as a capacitor having a capacitance value C41 amplified by the gain G2 of the second stage amplification circuit 40 and the gain G3 of the third stage amplification circuit 50 and having one end thereof connected to a reference potential. Thus, the first feedback capacitor 60′ in FIG. 3 can be equivalently represented as a capacitor with a capacitance of G2*G3*C41 having one end thereof connected to the node 32 and another end thereof connected to a reference potential. Here, the reference potential is a ground, for example, and the same applies hereafter.

The third feedback capacitor 74 has one end thereof connected to the output of the third stage amplification circuit 50 and another end thereof connected to the input of the second stage amplification circuit 40 via the third feedback resistor 76. Accordingly, the third feedback capacitor 74 can be regarded as a capacitor having a capacitance value C42 amplified by the gain G2 of the second stage amplification circuit 40 and the gain G3 of the third stage amplification circuit 50 and having one end thereof connected to a reference potential. Thus, the third feedback capacitor 74′ in FIG. 3 can be equivalently represented as a capacitor with a capacitance of G2*G3*C42 having one end thereof connected to the node 34 and another end thereof connected to a reference potential.

When a voltage at the first output terminal in the first differential amplification circuit 100 is denoted as +VO, a voltage at the second output terminal is denoted as −VO, a voltage at the node 32 is denoted as +VIN2, and a voltage at the node 34 is denoted as −VIN2, VIN2 is expressed by the transfer function of Expression 1 below. Here, in Expression 1, R111 represents a resistance value of the first filter resistor 402, R121 represents a resistance value of the third filter resistor 405, C111 represents a capacitance value of the first filter capacitor 404, R11 represents a resistance value of the first output resistor 120, G2 represents a gain of the second differential amplification circuit 200, G3 represents a gain of the third amplification circuit 300, C41 represents a capacitance value of the first feedback capacitor 60, and s represents Laplace operator of Laplace transform.

$$VIN 2 = ( 1 + s * ( R 111 - R 121 ) * C 111 ) / ( 1 + s * ( R 111 * C 111 + ( R 11 + R 121 ) * ( C 111 + G 2 * G 3 * C 41 ) ) + {s}^{2} * R 111 * ( R 11 + R 121 ) * G 2 * G 3 * C 41 * C 111 ) * VO \qquad ( 1 )$$

In Expression 1, the magnitude of G2*G3*C41 is sufficiently larger than the capacitance value C111 because the magnitude of the capacitance value C41 has been amplified by at least approximately several hundred times by the gain G2 of the second differential amplification circuit 200 and the gain G3 of the third amplification circuit 300. Thus, Expression 2 shown below holds.

$$C 111 + G 2 * G 3 * C 41 \approx G 2 * G 3 * C 41 \qquad ( 2 )$$

From Expression 1 and Expression 2, Expression 3 below is derived.

$$VIN 2 \approx ( 1 + s * ( R 111 - R 121 ) * C 111 ) / ( 1 + s * ( R 111 * C 111 + ( R 11 + R 121 ) * ( G 2 * G 3 * C 41 ) ) + {s}^{2} * R 111 * R 121 * G 2 * G 3 * C 41 * C 111 ) * VO = ( 1 + s * ( R 111 - R 121 ) * C 111 ) / ( ( 1 + s * ( R 11 + R 121 ) * G 2 * G 3 * C 41 ) * ( 1 + s * R 111 * C 111 ) ) * VO \qquad ( 3 )$$

(1+s*(R11+R121)*G2*G3*C41)*(1+s*R111*C111) shown in the denominator of Expression 3 indicates that there are two poles in the open-loop characteristic of the differential amplifier 10. In addition, as described above, G2*G3*C41 is larger compared to the capacitance value C111, and thus the first pole is calculated from (1+s*(R11+R121)*G2*G3*C41) and the second pole is calculated from (1+s*R111*C111). In addition, (1+s*(R111-R121)*C111) shown in the numerator of Expression 3 indicates that there is one zero point in the open-loop characteristic of the differential amplifier 10.

The first pole, the second pole, and the zero point in the open-loop characteristic of the differential amplifier 10 are calculated by Expression 3 and respectively expressed by Expression 4, Expression 5, and Expression 6 below.

$$The first pole = 1 / ( 2 π * ( R 11 + R 121 ) * G 2 * G 3 * C 41 ) \qquad ( 4 )$$

$$The second pole = 1 / ( 2 π * R 111 * C 111 ) \qquad ( 5 )$$

$$The zero point = 1 / ( 2 π * ( R 111 - R 121 ) * C 111 ) \qquad ( 6 )$$

Firstly, a configuration of the first pole expressed by Expression 4 will be described. (R11+R121) is the resistance through which the signal amplified by G1 times by the first differential amplification circuit 100 passes before being input to the second differential amplification circuit 200. G2*G3*C41 is the capacitance value amplified by the gain G2 of the second differential amplification circuit 200 and the gain G3 of the third amplification circuit 300 in the first feedback capacitor 60.

Then, a configuration of the second pole expressed by Expression 5 will be described. In a frequency domain in which the impedance of the capacitance value C111 of the first filter capacitor 404 becomes equivalent to or less than the resistance value R111 of the first filter resistor 402, the first output signal OP1 of the first differential amplification circuit 100 is transmitted to the fourth input terminal of the second differential amplification circuit 200 via the first filter resistor 402 and the first filter capacitor 404, and the differential signal transmitted from the first differential amplification circuit 100 to the second differential amplification circuit 200 is attenuated. The attenuation of the signal via the first filter resistor 402 and the first filter capacitor 404 occurs in a path different from the signal path via the resistance value R121 of the third filter resistor 405 which constitutes the first pole, and thus the second pole represented by Expression 5 is formed in association with the resistance value R111 and the capacitance value C111 apart from the first pole represented by Expression 4.

Then, a configuration of the zero point expressed by Expression 6 will be described. The zero point is related to a difference in resistance between the resistance value R111 of the first filter resistor 402 connected between the first output terminal of the first differential amplification circuit 100 and the fourth input terminal of the second differential amplification circuit 200 and the resistance value R121 of the third filter resistor 405 connected between the first output terminal of the first differential amplification circuit 100 and the third input terminal of the second differential amplification circuit 200. Although the attenuation through the signal path via the first filter resistor 402 and the first filter capacitor 404 becomes larger as the frequency becomes higher, the attenuation amount is limited in an even higher frequency range in which the impedance of the first filter capacitor 404 can be regarded as a short circuit, based on a ratio between the resistance values R111 and R121. In addition, in the even higher frequency range in which the impedance of the first filter capacitor 404 can be regarded as a short circuit, a phase delay by the first filter capacitor 404 is eliminated, and thus a phase delay that had been increased by the first filter capacitor 404 in the second pole of Expression 5 is canceled out by an advance of the phase in the even higher frequency range.

Note that, since the zero point has preferably a positive value for stable operation of the differential amplifier 10, the relationship between the resistance values R111 and R121 preferably satisfies Expression 7 below.

$$R 111 > R 121 \qquad ( 7 )$$

The first filter section 400 and the second filter section 403 of the present embodiment are respectively connected to a node between the first output terminal of the first differential amplification circuit 100 and the third input terminal of the second differential amplification circuit 200 and a node between the second output terminal of the first differential amplification circuit 100 and the fourth input terminal of the second differential amplification circuit 200. Accordingly, as shown in the equivalent circuit, the first filter section 400 and the second filter section 403 are not in a parallel connection relationship with G2*G3*C41 and G2*G3*C 42 of a sufficiently large capacitance, allowing the second pole and the zero point to be generated.

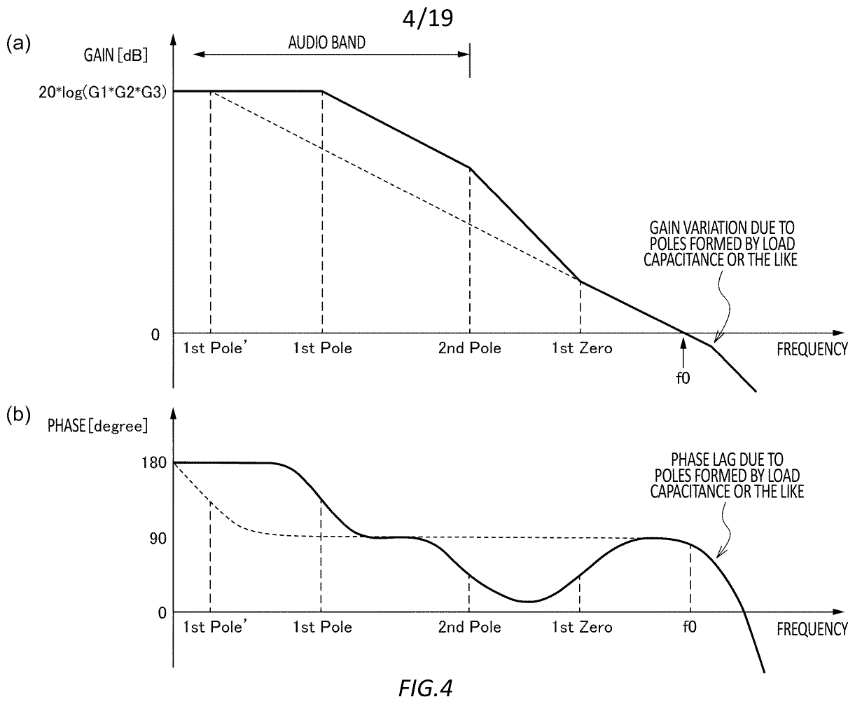

FIG. 4 illustrates a gain and a phase characteristic in an open-loop of the differential amplifier 10 of the present embodiment. In FIG. 4, (a) shows a relationship between the gain and the frequency of the input signals INP1, INN1 of the differential amplifier 10, and (b) shows a relationship between the phase of the output signals ON3, OP3 and the frequency of the input signals INP1, INN1 of the differential amplifier 10.

In (a) and (b) in FIG. 4, the solid line represents a gain and a phase characteristic in a practical open-loop in which the frequency at the second pole and the frequency at the zero point have been adjusted for stable operation of the differential amplifier 10. In FIG. 4, 1st Pole represents the frequency at the first pole, 2nd Pole represents the frequency at the second pole, and 1st Zero represents the frequency at the zero point. In (a) and (b) in FIG. 4, the dotted line schematically represents a gain and a phase characteristic in an open-loop of a differential amplifier of a reference example without including the RC filter 30. In FIG. 4, 1st Pole′ represents the frequency at the first pole in the differential amplifier of the reference example.

As shown in FIG. 4, in a frequency range from the frequency zero (DC) to the frequency at the first pole, the gain is equal to G1*G2*G3, which is the DC gain, and in the frequency range between the first pole and the second pole, it attenuates at 20 dB/dec. In addition, in the frequency range between the second pole and the zero point, the gain attenuates at 40 dB/dec, and when the frequency exceeds the zero point, the gain attenuates at 20 dB/dec again.

Now, the phase characteristic in the open-loop of the differential amplifier 10 of the present embodiment will be described. When the frequency exceeds the second pole, the phase delay approaches 180 degrees, but does not reach 180 degrees. Subsequently, as the frequency approaches the zero point, the phase advances. In the vicinity of the unity gain frequency f0 shown in FIG. 4, the phase delay by the second pole and the phase advance by the zero point cancel each other out, and only 90 degrees, which is the phase delay by the first pole, remain.

Then, an adjustment of the unity gain frequency f0 of the differential amplifier 10 of the present embodiment will be described. The pole generated due to the load capacitance or the like of the differential amplifier 10 causes a phase delay exceeding 180 degrees as shown in FIG. 4. For stable operation of the differential amplifier 10 of the present embodiment, f0 is preferably set to a frequency lower than the frequency of the pole generated due to the load capacitance or the like of the differential amplifier 10. However, as shown in FIG. 4, it is not necessarily required to adjust the position of the first pole to a lower frequency, and it is possible to design the unity gain frequency f0 of the differential amplifier 10 to be equivalent to the unity gain frequency of the differential amplifier 10 of the reference example by the adjustment of the second pole and the zero point.

As shown in FIG. 4, it can be seen that the differential amplifier 10 of the present embodiment has a higher gain in the audio band, because it can include the first pole arranged at a relatively high frequency. In addition, the RC filter 30 of the first circuit example includes a smaller number of elements, allowing a reduction in cost increase, and requires no constant power consumption, achieving low power consumption.

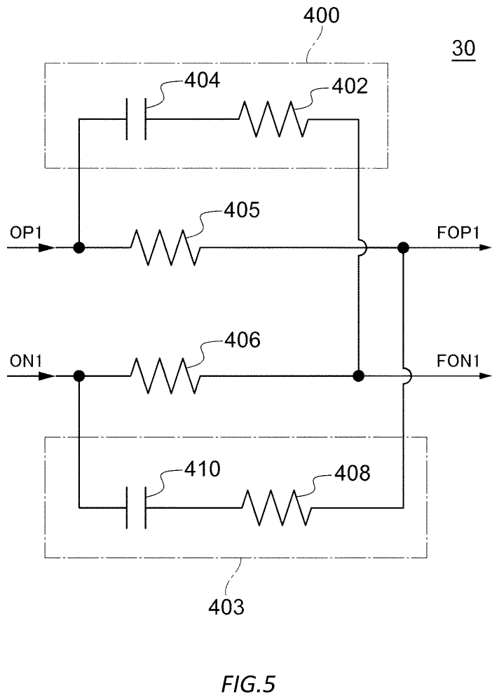

FIG. 5 shows a second circuit example of the RC filter 30 in the differential amplifier 10 of the present embodiment. The RC filter 30 of the second circuit example may be similar to the RC filter 30 of the first circuit example, except for the connection relationship of the filter resistor and the filter capacitor. In the following, differences from the RC filter 30 of the first circuit example are mainly described.

The first filter resistor 402 has one end thereof connected to the node between the second output terminal of the first differential amplification circuit 100 and the fourth input terminal of the second differential amplification circuit 200 and another end thereof connected to one end of the first filter capacitor 404. The first filter capacitor 404 has another end thereof connected to a node between the first output terminal of the first differential amplification circuit 100 and the third input terminal of the second differential amplification circuit 200. The first filter resistor 402 may have a resistance value larger than that of the third filter resistor 405.

The second filter resistor 408 has one end thereof connected between the node to which the another end of the first filter capacitor 404 is connected and the third input terminal of the second differential amplification circuit 200 and another end thereof connected to one end of the second filter capacitor 410. The second filter capacitor 410 has another end thereof connected between the second output terminal of the first differential amplification circuit 100 and the node to which the one end of the first filter resistor 402 is connected. In the second circuit example, the second filter resistor 408 may have the same resistance value as the first filter resistor 402. The second filter capacitor 410 may have the same capacitance value as the first filter capacitor 404. The second filter resistor 408 may have a resistance value that is larger than that of the fourth filter resistor 406.

The differential amplifier 10 including such RC filter 30 of the second circuit example is also equivalent, as an equivalent circuit, to the first circuit example shown in FIG. 3 and thus the gain and the phase characteristic similar to those of the differential amplifier 10 including the first circuit example as shown in FIG. 4 can be obtained. In addition, the RC filter 30 of the second circuit example includes a smaller number of elements, allowing a reduction in cost increase, and requires no constant power consumption, achieving low power consumption.

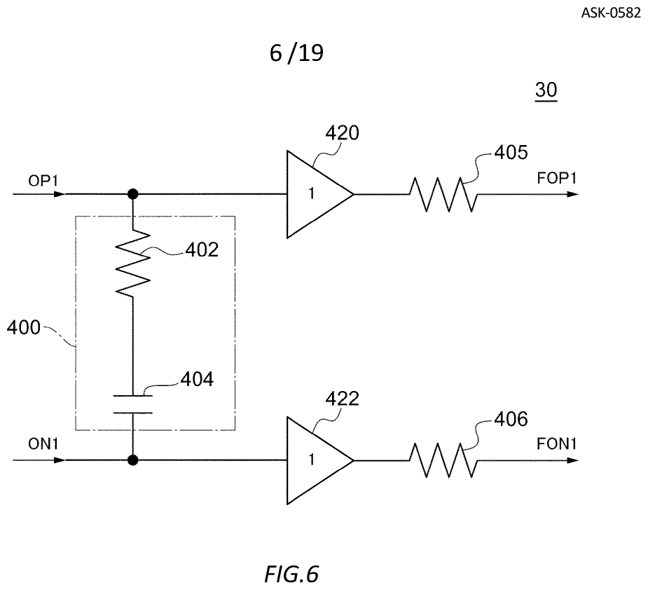

FIG. 6 shows a third circuit example of the RC filter 30 in the differential amplifier 10 of the present embodiment. The RC filter 30 of the third circuit example may be similar to the RC filter 30 of the first circuit example, except that it does not have the second filter section 403 but includes a first buffer 420 and a second buffer 422. In the following, differences from the RC filter 30 of the first circuit example are mainly described.

The first filter resistor 402 has one end thereof connected to the node between the first output terminal of the first differential amplification circuit 100 and the third input terminal of the second differential amplification circuit 200 and another end thereof connected to one end of the first filter capacitor 404. The first filter capacitor 404 has another end thereof connected to a node between the second output terminal of the first differential amplification circuit 100 and the fourth input terminal of the second differential amplification circuit 200.

The first buffer 420 has an input thereof connected to the first output terminal of the first differential amplification circuit 100 and an output thereof connected to the third input terminal of the second differential amplification circuit 200. In the present embodiment, the first buffer 420 is connected between the node to which the one end of the first filter resistor 402 is connected and the one end of the third filter resistor 405. The first buffer 420 may have an input-output gain of one time and preferably has a low input-output delay. Accordingly, the first buffer 420 may be, for example, a source follower with the use of a MOS transistor or an emitter follower with the use of a bipolar transistor, and may multiply a signal OP1 input by one for output.

The second buffer 422 has an input thereof connected to the second output terminal of the first differential amplification circuit 100 and an output thereof connected to the fourth input terminal of the second differential amplification circuit 200. In the present embodiment, the second buffer 422 is connected between the node to which the another end of the first filter capacitor 404 is connected and the one end of the fourth filter resistor 406. The second buffer 422 may have an input-output gain of one time and preferably has a low input-output delay. Accordingly, the second buffer 422 may be, for example, a source follower with the use of a MOS transistor or an emitter follower with the use of a bipolar transistor, and may multiply a signal ON1 input by one for output.

The third filter resistor 405 has another end thereof connected to the third input terminal of the second differential amplification circuit 200. The fourth filter resistor 406 has another end thereof connected to the fourth input terminal of the second differential amplification circuit 200. The fourth filter resistor 406 may have a resistance value that is the same as that of the third filter resistor 405.

The RC filter 30 of the third circuit example has a configuration in which the transmission circuit is dissociated before and after the first buffer 420 and the second buffer 422. With this configuration, the transmission circuit before the first buffer 420 and the second buffer 422 can generate the second pole and the zero point, and the transmission circuit after the first buffer 420 and the second buffer 422 can generate the first pole. The first buffer 420 and the second buffer 422 dissociate the first filter capacitor 404 from the first feedback capacitor 60 and the second feedback capacitor 64, and thus the first feedback capacitor 60 and the third feedback capacitor 74 do not affect the pole or the zero point generated in association with the first filter capacitor 404.

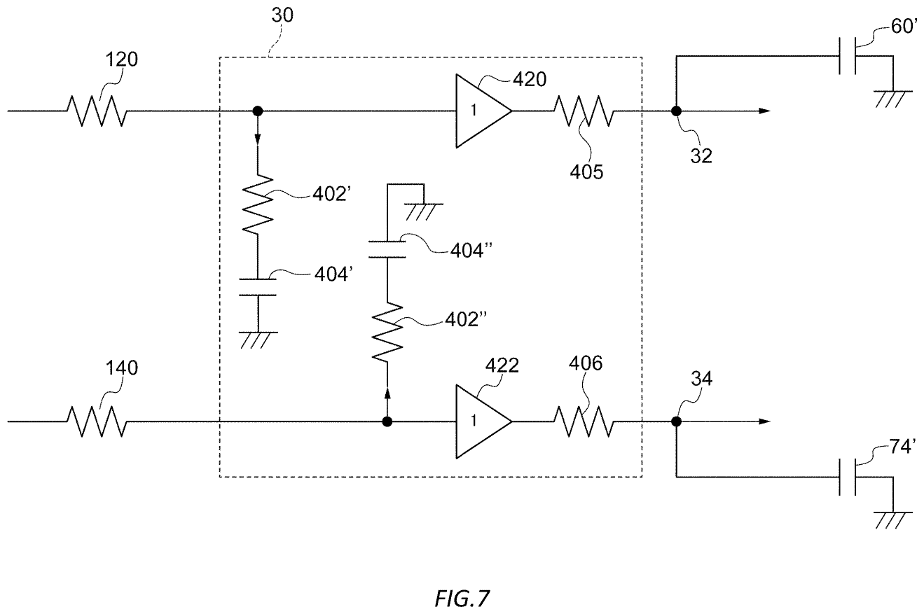

FIG. 7 shows an equivalent circuit of a part of the differential amplifier 10 provided with the RC filter 30 of the third circuit example. FIG. 7 shows, as the equivalent circuit, a transmission circuit where the signal amplified by G1 times in the first stage amplification circuit 20 is input to the second stage amplification circuit 40 via the RC filter 30. In the equivalent circuit shown in FIG. 7, omission of some elements or resizing of elements has been equivalently performed as well as change of wiring has also been equivalently performed on the transmission circuit of the differential amplifier 10. Note that, in FIG. 7, the first feedback resistor 62 and the third feedback resistor 76 are omitted because they are elements to adjust the phase characteristic of the differential amplifier 10 and also elements that do not contribute to the first pole, the second pole, and the zero point.

The first feedback capacitor 60 can be equivalently represented as a capacitor 60′ with a capacitance value of G1*G2*C41 having one end thereof connected to the node 32 and another end thereof connected to a reference potential. The third feedback capacitor 74 can be equivalently represented as a capacitor 74′ with a capacitance value of G1*G2*C42 having one end thereof connected to the node 34 and another end thereof connected to a reference potential. The nodes to which the first filter resistor 402 and the first filter capacitor 404 are connected are differential nodes in the differential amplifier 10, and thus the voltages at these nodes are each signals having the same magnitude but phase inverted with each other. Accordingly, in FIG. 7, the transmission circuit is equivalently represented as a circuit in which one end of a resistor 402′ with a resistance value of half the magnitude of the resistance value of the first filter resistor 402 is connected to the node to which the first filter resistor 402 is connected, another end of the resistor 402′ is connected to one end of a capacitor 404′ with a capacitance value of twice the magnitude of the capacitance value of the first filter capacitor 404, and another end of the capacitor 404′ is connected to a reference potential. In addition, the transmission circuit is equivalently represented as the circuit in which one end of a resistor 402″ with a resistance value of half the magnitude of the resistance value of the first filter resistor 402 is connected to the node to which the first filter capacitor 404 is connected, another end of the resistor 402″ is connected to one end of a capacitor 404″ with a capacitance value of twice the magnitude of the capacitance value of the first filter capacitor 404, and another end of the capacitor 404″ is connected to a reference potential.

When a voltage at the first output terminal in the first differential amplification circuit 100 is denoted as +VO, a voltage at the second output terminal is denoted as −VO, a voltage at the node 32 is denoted as +VIN2, and a voltage at the node 34 is denoted as −VIN2, VIN2 is expressed by the transfer function of Expression 8 below. Here, in Expression 8, R150 represents a resistance value of the first filter resistor 402, R161 represents a resistance value of the third filter resistor 405, C150 represents a capacitance value of the first filter capacitor 404, R11 represents a resistance value of the first output resistor 120, G2 represents a gain of the second differential amplification circuit 200, G3 represents a gain of the third amplification circuit 300, C41 represents a capacitance value of the first feedback capacitor 60, and s represents Laplace operator of Laplace transform.

$$VIN 2 = ( ( 1 + s * R 151 * C 151 ) / ( 1 + s * ( 2 * R 11 + R 150 ) * C 150 ) ) * ( 1 / ( 1 + s * R 161 * G 2 * G 3 * C 41 ) ) * VO = ( 1 + s * R 150 * C 150 ) / ( ( 1 + s * R 161 * G 2 * G 3 * C 41 ) * ( 1 + s * ( 2 * R 11 + R 150 ) * C 150 ) ) * VO \qquad ( 8 )$$

(1+s*R161*G2*G3*C41)*(1+s*(2*R11+R150)*C150) shown in the denominator of Expression 8 indicates that there are two poles in the open-loop characteristic of the differential amplifier 10. In addition, G2*G3*C41 is larger compared to C150, and thus the first pole is calculated from (1+s*R161*G2*G3*C41) and the second pole is calculated from (1+s*(2*R11+R150)*C150). In addition, (1+s*R150*C150) shown in the numerator of Expression 8 indicates that there is one zero point in the open-loop characteristic of the differential amplifier 10.

The first pole, the second pole, and the zero point in the open-loop characteristic of the differential amplifier 10 are calculated by Expression 8 and respectively expressed by Expression 9, Expression 10, and Expression 11 below.

$$The first pole = 1 / ( 2 π * R 161 * G 2 * G 3 * C 41 ) \qquad ( 9 )$$

$$The second pole = 1 / ( 2 π * ( 2 * R 11 + R 150 ) * C 150 ) \qquad ( 10 )$$

$$The zero point = 1 / ( 2 π * R 150 * C 150 ) \qquad ( 11 )$$

As expressed by Expression 9 representing the frequency at the first pole, the first pole is not affected by R11 or R12, which are output impedances in the first stage amplification circuit 20 generated when the RC filter 30 of the first circuit example is used, because of the first buffer 420 and the second buffer 422 added inside the RC filter 30. Thus, a deviation of frequency at the first pole in mass production can be suppressed to be lower in the case in which the RC filter 30 of the third circuit example is used compared to the case in which the RC filter 30 of the first circuit example is used.

In addition, the first filter resistor 402 and the first filter capacitor 404 connected in series in the RC filter 30 are dissociated from G2*G3*C41 and G2*G3*C 42 with a sufficiently large capacitance by the first buffer 420 and the second buffer 422, and are not in a parallel relationship. Thus, the second pole and the zero point can be generated by the RC filter 30.

In the RC filter 30 of the third circuit example, an impedance of a circuit connected to the first input terminal and an impedance of a circuit connected to the second input terminal in the first differential amplification circuit 100 are equal. The fourth circuit example to the eighth circuit example are shown below which can prevent deterioration of the performance of the differential amplifier 10 in a design situation in which a parasitic capacitance of one end of the first filter capacitor 404 is different from a parasitic capacitance of another end thereof.

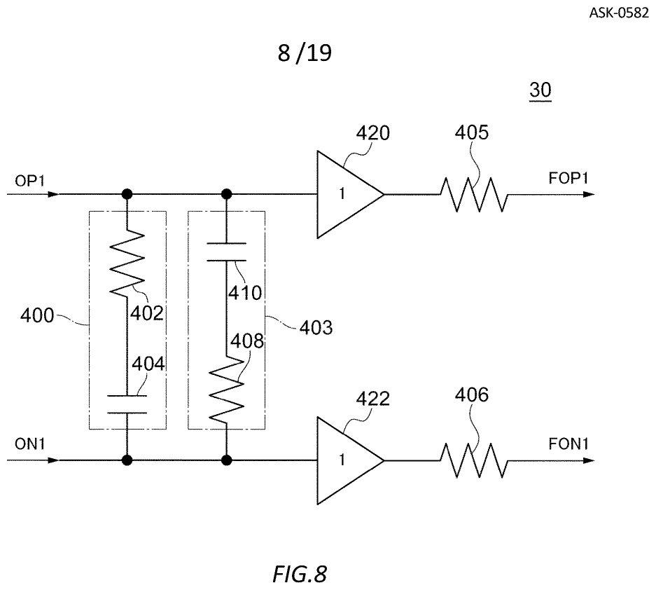

FIG. 8 shows a fourth circuit example of the RC filter 30 in the differential amplifier 10 of the present embodiment. The RC filter 30 of the fourth circuit example may be the similar to the RC filter 30 of the third circuit example, except that it includes the second filter section 403. In the following, differences from the RC filter 30 of the third circuit example are mainly described.

The second filter section 403 is connected in parallel with the first filter section 400. The second filter section 403 includes a second filter resistor 408 and a second filter capacitor 410 connected in series. The second filter resistor 408 has one end thereof connected to a node between the node to which the first filter capacitor 404 is connected and the input of the second buffer 422 and another end thereof connected to one end of the second filter capacitor 410. The second filter capacitor 410 has another end thereof connected to a node between the node to which the one end of the first filter resistor 402 is connected and the input of the first buffer 420. The second filter resistor 408 may have the same resistance value as the first filter resistor 402, and the second filter capacitor 410 may have the same capacitance value as the first filter capacitor 404. The differential amplifier 10 including such RC filter 30 of the fourth circuit example is also equivalent, as an equivalent circuit, to the third circuit example shown in FIG. 7 and thus the gain and the phase characteristic similar to those of the differential amplifier 10 including the third circuit example can be obtained.

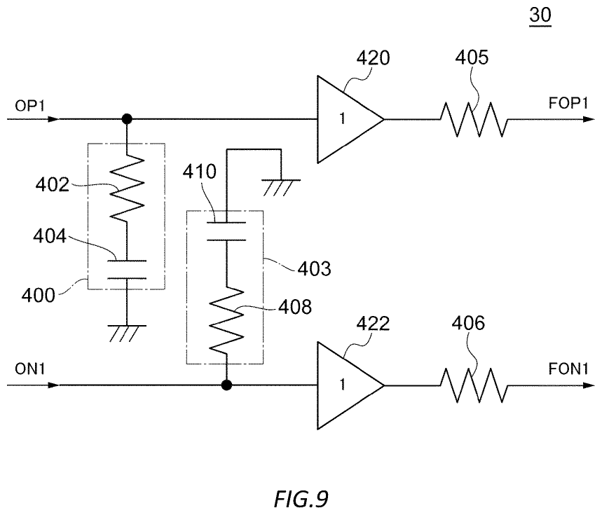

FIG. 9 shows a fifth circuit example of the RC filter 30 in the differential amplifier 10 of the present embodiment. The RC filter 30 of the fifth circuit example may be similar to the RC filter 30 of the fourth circuit example, except that one end of the first filter section 400 and one end of the second filter section 403 are connected to reference potentials. In the following, differences from the RC filter 30 of the fourth circuit example are mainly described.

The first filter section 400 has one end thereof connected to a node between the first output terminal of the first differential amplification circuit 100 and the third input terminal of the second differential amplification circuit 200 and another end thereof connected to a reference potential. The first filter section 400 includes a first filter resistor 402 and a first filter capacitor 404 connected in series. The first filter resistor 402 has one end thereof connected to a node between the first output terminal of the first differential amplification circuit 100 and the input of the first buffer 420 and another end thereof connected to the one end of the first filter capacitor 404. The first filter capacitor 404 has another end thereof connected to a reference potential.

The second filter section 403 has one end thereof connected to a node between the second output terminal of the first differential amplification circuit 100 and the fourth input terminal of the second differential amplification circuit 200 and another end thereof connected to a reference potential. The second filter section 403 includes a second filter resistor 408 and a second filter capacitor 410 connected in series. The second filter resistor 408 has one end thereof connected to a node between the second output terminal of the first differential amplification circuit 100 and the input of the second buffer 422 and another end thereof connected to one end of the second filter capacitor 410. The second filter capacitor 410 has another end thereof connected to a reference potential. The second filter resistor 408 may have the same resistance value as the first filter resistor 402, and the second filter capacitor 410 may have the same capacitance value as the first filter capacitor 404.

The differential amplifier 10 including such RC filter 30 of the fifth circuit example is also equivalent, as an equivalent circuit, to the third circuit example shown in FIG. 7 and thus the gain and the phase characteristic similar to those of the differential amplifier 10 including the third circuit example can be obtained.

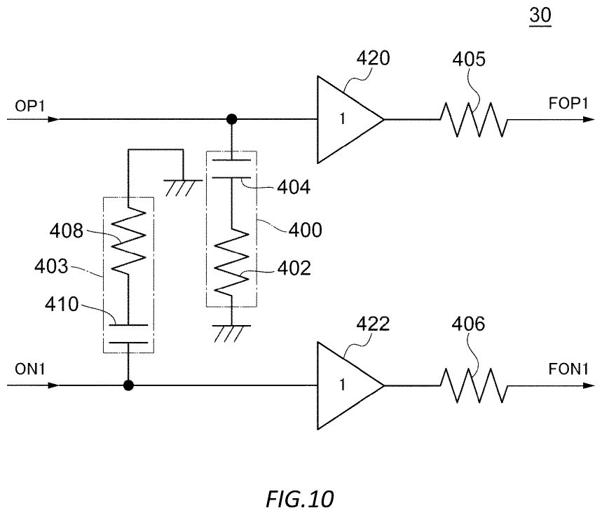

FIG. 10 shows a sixth circuit example of the RC filter 30 in the differential amplifier 10 of the present embodiment. The RC filter 30 of the sixth circuit example may be similar to the RC filter 30 of the fifth circuit example, except that the first filter resistor 402 and the second filter resistor 408 are connected to reference potentials. In the following, differences from the RC filter 30 of the fifth circuit example are mainly described.

The first filter section 400 includes a first filter resistor 402 and a first filter capacitor 404 connected in series. The first filter resistor 402 has one end thereof connected to a reference potential and another end thereof connected to one end of the first filter capacitor 404. The first filter capacitor 404 has another end thereof connected to a node between the first output terminal of the first differential amplification circuit 100 and the input of the first buffer 420.

The second filter section 403 includes a second filter resistor 408 and a second filter capacitor 410 connected in series. The second filter resistor 408 has one end thereof connected to a reference potential and another end thereof connected to one end of the second filter capacitor 410. The second filter capacitor 410 has another end thereof connected to a node between the second output terminal of the first differential amplification circuit 100 and the input of the second buffer 422. The second filter resistor 408 may have the same resistance value as the first filter resistor 402, and the second filter capacitor 410 may have the same capacitance value as the first filter capacitor 404.

The differential amplifier 10 including such RC filter 30 of the sixth circuit example is also equivalent, as an equivalent circuit, to the third circuit example shown in FIG. 7 and thus the gain and the phase characteristic similar to those of the differential amplifier 10 including the third circuit example can be obtained.

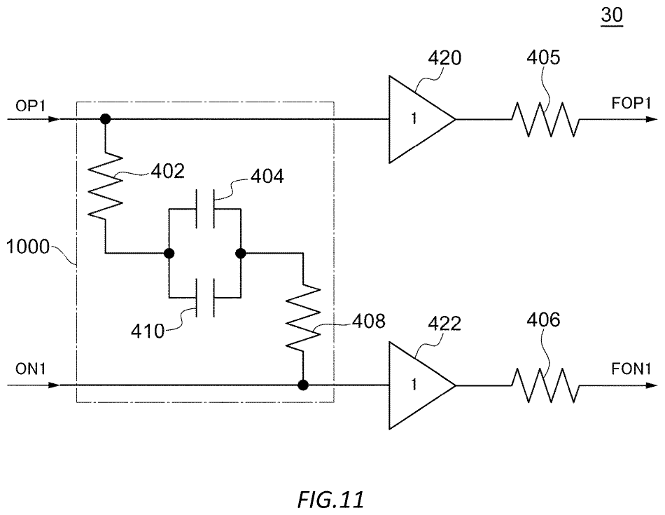

FIG. 11 shows a seventh circuit example of the RC filter 30 in the differential amplifier 10 of the present embodiment. The RC filter 30 of the seventh circuit example may be similar to the RC filter 30 of the third circuit example, except that it includes a filter section 1000 with a different configuration. In the following, differences from the RC filter 30 of the third circuit example are mainly described.

The filter section 1000 includes the first filter resistor 402, the first filter capacitor 404, the second filter resistor 408, and the second filter capacitor 410. The first filter resistor 402 has one end thereof connected to a node between the first output terminal of the first differential amplification circuit 100 and the third input terminal of the second differential amplification circuit 200. In the present embodiment, the first filter resistor 402 has one end thereof connected to a node between the first output terminal of the first differential amplification circuit 100 and the input of the first buffer 420 and another end thereof connected to one end of the first filter capacitor 404 and one end of the second filter capacitor 410.

The first filter capacitor 404 is connected between the another end of the first filter resistor 402 and another end of the second filter resistor 408 in parallel with the second filter capacitor 410. The first filter capacitor 404 and the second filter capacitor 410 each have another end thereof connected to the another end of the second filter resistor 408. The second filter resistor 408 has one end thereof connected to a node between the second output terminal of the first differential amplification circuit 100 and the fourth input terminal of the second differential amplification circuit 200. In the present embodiment, the second filter resistor 408 has another end thereof connected to a node between the second output terminal of the first differential amplification circuit 100 and the input of the second buffer 422. The second filter resistor 408 may have the same resistance value as the first filter resistor 402, and the second filter capacitor 410 may have the same capacitance value as the first filter capacitor 404.

The differential amplifier 10 including such RC filter 30 of the seventh circuit example is also equivalent, as an equivalent circuit, to the third circuit example shown in FIG. 7 and thus the gain and the phase characteristic similar to those of the differential amplifier 10 including the third circuit example can be obtained.

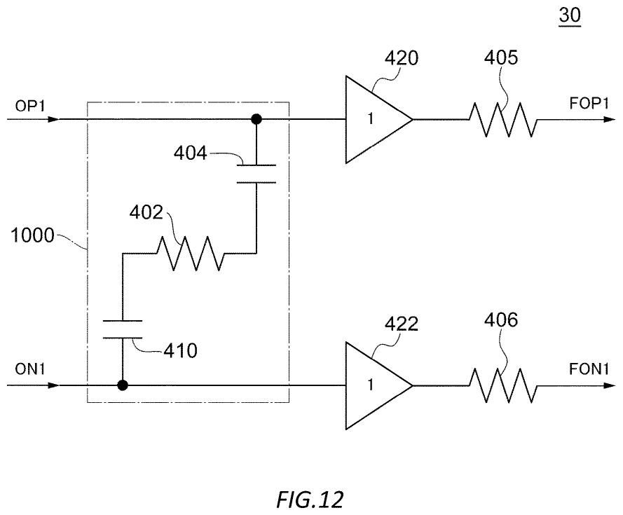

FIG. 12 shows an eighth circuit example of the RC filter 30 in the differential amplifier 10 of the present embodiment. The RC filter 30 of the eighth circuit example may be similar to the RC filter 30 of the third circuit example, except that it includes a filter section 1000 with a different configuration. In the following, differences from the RC filter 30 of the third circuit example are mainly described.

The filter section 1000 includes the first filter capacitor 404, the second filter capacitor 410, and the first filter resistor 402. The first filter capacitor 404 has one end thereof connected to a node between the first output terminal of the first differential amplification circuit 100 and the third input terminal of the second differential amplification circuit 200. In the present embodiment, the first filter capacitor 404 has one end thereof connected to a node between the first output terminal of the first differential amplification circuit 100 and the input of the first buffer 420 and another end thereof connected to one end of the first filter resistor 402. The second filter capacitor 410 has one end thereof connected to a node between the second output terminal of the first differential amplification circuit 100 and the fourth input terminal of the second differential amplification circuit 200. In the present embodiment, the second filter capacitor 410 has one end thereof connected to a node between the second output terminal of the first differential amplification circuit 100 and the input of the second buffer 422 and another end thereof connected to another end of the first filter resistor 402. The first filter resistor 402 is connected between another end of the first filter capacitor 404 and another end of the second filter capacitor 410. The second filter capacitor 410 may have the same capacitance value as the first filter capacitor 404.

The differential amplifier 10 including such RC filter 30 of the eighth circuit example is also equivalent, as an equivalent circuit, to the third circuit example shown in FIG. 7 and thus the gain and the phase characteristic similar to those of the differential amplifier 10 including the third circuit example can be obtained.

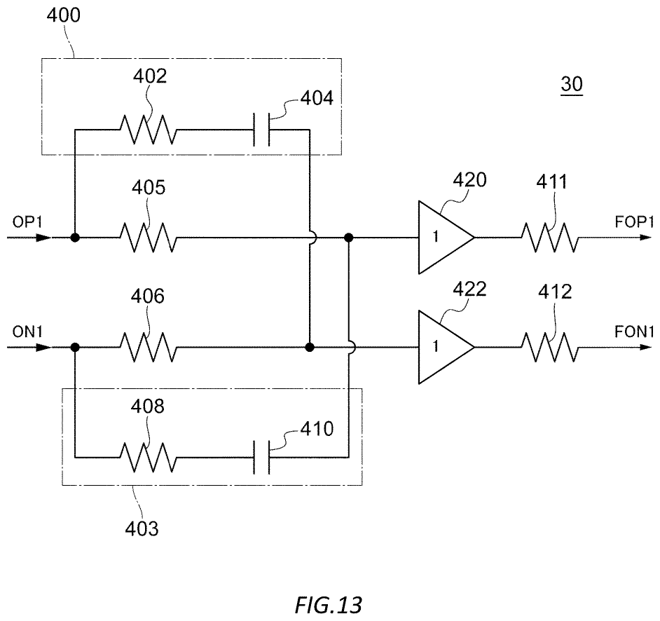

FIG. 13 shows a ninth circuit example of the RC filter 30 in the differential amplifier 10 of the present embodiment. The RC filter 30 of the ninth circuit example may be similar to the RC filter 30 of the first circuit example, except that it further includes the first buffer 420 and the second buffer 422 similar to those of the third circuit example. In the following, differences from the RC filter 30 of the first circuit example are mainly described.

The RC filter 30 of the ninth circuit example includes the first filter section 400, the second filter section 403, the third filter resistor 405, the fourth filter resistor 406, the first buffer 420, the second buffer 422, a fifth filter resistor 411, and a sixth filter resistor 412.

The first filter section 400 includes a first filter resistor 402 and a first filter capacitor 404 connected in series. The first filter resistor 402 has one end thereof connected to a node between the first output terminal of the first differential amplification circuit 100 and one end of the third filter resistor 405 and another end thereof connected to one end of the first filter capacitor 404. The first filter capacitor 404 has another end thereof connected to a node between one end of the fourth filter resistor 406 and the input of the second buffer 422.

The second filter section 403 includes a second filter resistor 408 and a second filter capacitor 410 connected in series. The second filter resistor 408 has one end thereof connected to a node between the second output terminal of the first differential amplification circuit 100 and another end of the fourth filter resistor 406 and another end thereof connected to one end of the second filter capacitor 410. The second filter capacitor 410 has another end thereof connected to a node between another end of the third filter resistor 405 and the input of the first buffer 420.

The third filter resistor 405 is connected between the first output terminal of the first differential amplification circuit 100 and the input of the first buffer 420. The fourth filter resistor 406 is connected between the second output terminal of the first differential amplification circuit 100 and the input of the second buffer 422. The first buffer 420 has an output thereof connected to one end of the fifth filter resistor 411. The second buffer 422 has an output thereof connected to one end of the sixth filter resistor 412. The first buffer 420 and the second buffer 422 may be similar to the third circuit example. The fifth filter resistor 411 has another end thereof connected to the third input terminal of the second differential amplification circuit 200. The sixth filter resistor 412 has another end thereof connected to the fourth input terminal of the second differential amplification circuit 200.

In the ninth circuit example, the first filter resistor 402 may have a resistance value that is the same as that of the second filter resistor 408 and that is larger than that of the third filter resistor 405. The second filter resistor 408 may have a resistance value that is larger than that of the fourth filter resistor 406. The fourth filter resistor 406 may have a resistance value that is the same as that of the third filter resistor 405. The sixth filter resistor 412 may have a resistance value that is the same as that of the fifth filter resistor 411. The second filter capacitor 410 may have the same capacitance value as the first filter capacitor 404.

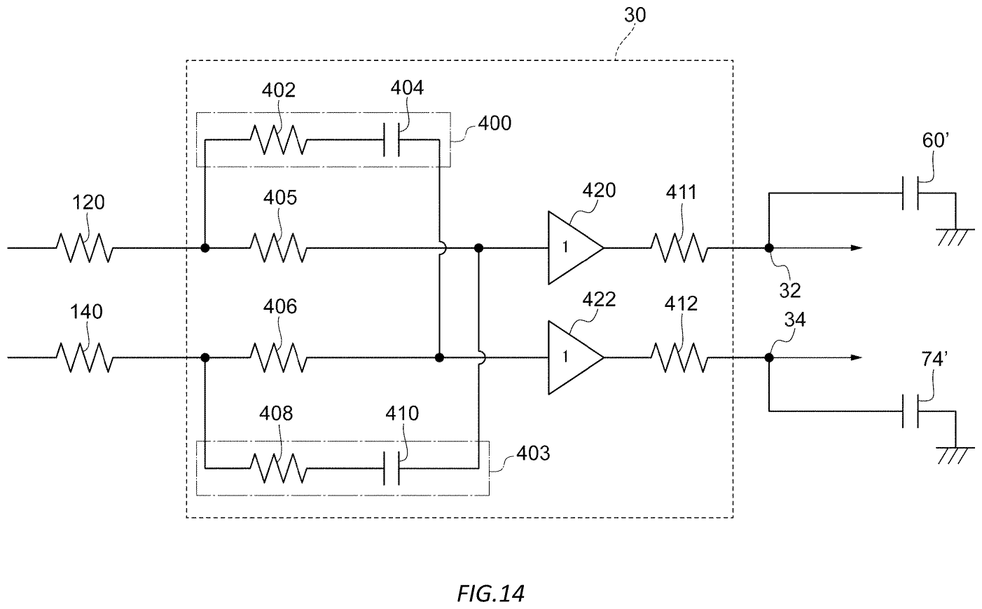

FIG. 14 shows an equivalent circuit of a part of the differential amplifier 10 provided with the RC filter 30 of the ninth circuit example. FIG. 14 shows, as the equivalent circuit, a transmission circuit where the signal amplified by G1 times in the first stage amplification circuit 20 is input to the second stage amplification circuit 40 via the RC filter 30. In the equivalent circuit shown in FIG. 14, omission of some elements or resizing of elements has been equivalently performed as well as change of wiring has also been equivalently performed on the transmission circuit of the differential amplifier 10. Note that, in FIG. 14, the first feedback resistor 62 and the third feedback resistor 76 are omitted because they are elements to adjust the phase characteristic of the differential amplifier 10 and also elements that do not contribute to the first pole, the second pole, and the zero point.

The first feedback capacitor 60 has one end thereof connected to the output of the third stage amplification circuit 50 and another end thereof connected to the input of the second stage amplification circuit 40 via the first feedback resistor 62. Accordingly, the first feedback capacitor 60 can be regarded as a capacitor having a capacitance value C41 amplified by the gain G2 of the second stage amplification circuit 40 and the gain G3 of the third stage amplification circuit 50 and having one end thereof connected to a reference potential. Thus, the first feedback capacitor 60′ in FIG. 14 can be equivalently represented as a capacitor with a capacitance of G1*G2*C41 having one end thereof connected to the node 32 and another end thereof connected to a reference potential.

The third feedback capacitor 74 has one end thereof connected to the output of the third stage amplification circuit 50 and another end thereof connected to the input of the second stage amplification circuit 40 via the third feedback resistor 76. Accordingly, the third feedback capacitor 74 can be regarded as a capacitor having a capacitance value C42 amplified by the gain G2 of the second stage amplification circuit 40 and the gain G3 of the third stage amplification circuit 50 and having one end thereof connected to a reference potential. Thus, the third feedback capacitor 74′ in FIG. 14 can be equivalently represented as a capacitor with a capacitance of G1*G2*C42 having one end thereof connected to the node 34 and another end thereof connected to a reference potential.

When a voltage at the first output terminal in the first differential amplification circuit 100 is denoted as +VO, a voltage at the second output terminal is denoted as −VO, a voltage at the node 32 is denoted as +VIN2, and a voltage at the node 34 is denoted as −VIN2, VIN2 is expressed by the transfer function of Expression 12 below. Here, in Expression 12, R271 represents a resistance value of the first filter resistor 402, R281 represents a resistance value of the third filter resistor 405, R291 represents a resistance value of the fifth filter resistor 411, C271 represents a capacitance value of the first filter capacitor 404, R11 represents a resistance value of the first output resistor 120, G2 represents a gain of the second differential amplification circuit 200, G3 represents a gain of the third amplification circuit 300, C41 represents a capacitance value of the first feedback capacitor 60, and s represents Laplace operator of Laplace transform.

$$VIN 2 = ( ( 1 + s * ( R 271 - R 281 ) * C 271 ) / ( 1 + s * ( 4 * R 11 + R 271 + R 281 ) * C 271 ) ) * ( 1 / ( 1 + s * R 291 * G 2 * G 3 * C 41 ) ) * VO = ( 1 + s * ( R 271 - R 281 ) * C 271 ) / ( ( 1 + s * R 291 * G 2 * G 3 * C 41 ) * ( 1 + s * ( 4 * R 11 + R 271 + R 281 ) * C 271 ) ) * VO \qquad ( 12 )$$

(1+s*R291*G2*G3*C41)*(1+s*(4*R11+R271+R281)*C271) shown in the denominator of Expression 12 indicates that there are two poles in the open-loop characteristic of the differential amplifier 10. In addition, G2*G3*C41 is larger compared to C271, and thus the first pole is calculated from (1+s*R291*G2*G3*C41) and the second pole is calculated from (1+s*(4*R11+R271+R281)*C271). In addition, (1+s*(R271−R281)*C271) shown in the numerator of Expression 12 indicates that there is one zero point in the open-loop characteristic of the differential amplifier 10.

The first pole, the second pole, and the zero point in the open-loop characteristic of the differential amplifier 10 are calculated by Expression 12 and respectively expressed by Expression 13, Expression 14, and Expression 15 below.

$$The first pole = 1 / ( 2 π * R 291 * G 2 * G 3 * C 41 ) \qquad ( 13 )$$

$$The second pole = 1 / ( 2 π * ( 4 * R 11 + R 271 + R 281 ) * C 271 ) \qquad ( 14 )$$

$$The zero point = 1 / ( 2 π * ( R 271 - R 281 ) * C 271 ) \qquad ( 15 )$$

As expressed by Expression 13, the first pole is not affected by the first output resistor 120 and the second output resistor 140, which are output impedances in the first stage amplification circuit 20 that can be generated when the RC filter 30 of the first circuit example is used, because of the first buffer 420 and the second buffer 422 added to the RC filter 30. Thus, a deviation of frequency at the first pole in mass production can be suppressed to be lower in the case in which the RC filter 30 of the ninth circuit example is used compared to the case in which the RC filter 30 of the first circuit example is used.

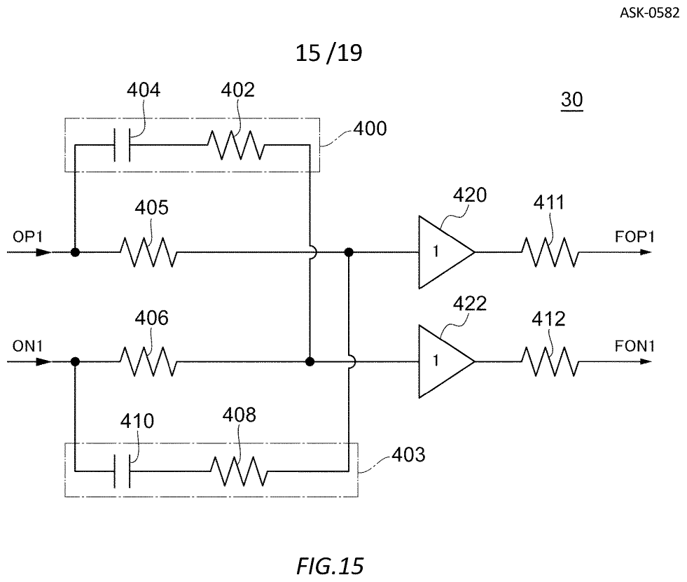

FIG. 15 shows a tenth circuit example of the RC filter 30 in the differential amplifier 10 of the present embodiment. The RC filter 30 of the tenth circuit example may be similar to the RC filter 30 of the ninth circuit example, except for the connection relationship of the filter resistor and the filter capacitor. In the following, differences from the RC filter 30 of the ninth circuit example are mainly described.

The first filter resistor 402 has one end thereof connected to a node between one end of the fourth filter resistor 406 and the input of the second buffer 422 and another end thereof connected to one end of the first filter capacitor 404. The first filter capacitor 404 has another end thereof connected to a node between the first output terminal of the first differential amplification circuit 100 and the one end of the third filter resistor 405.

The second filter resistor 408 has one end thereof connected to a node between another end of the third filter resistor 405 and the input of the first buffer 420 and another end thereof connected to one end of the second filter capacitor 410. The second filter capacitor 410 has another end thereof connected to a node between the second output terminal of the first differential amplification circuit 100 and another end of the fourth filter resistor 406. In the tenth circuit example, the second filter resistor 408 may have the same resistance value as the first filter resistor 402. The second filter capacitor 410 may have the same capacitance value as the first filter capacitor 404. The first filter resistor 402 may have a resistance value larger than that of the third filter resistor 405. The second filter resistor 408 may have a resistance value that is larger than that of the fourth filter resistor 406.

The differential amplifier 10 including such RC filter 30 of the tenth circuit example is also equivalent, as an equivalent circuit, to the ninth circuit example shown in FIG. 14 and thus the gain and the phase characteristic similar to those of the differential amplifier 10 including the ninth circuit example can be obtained.

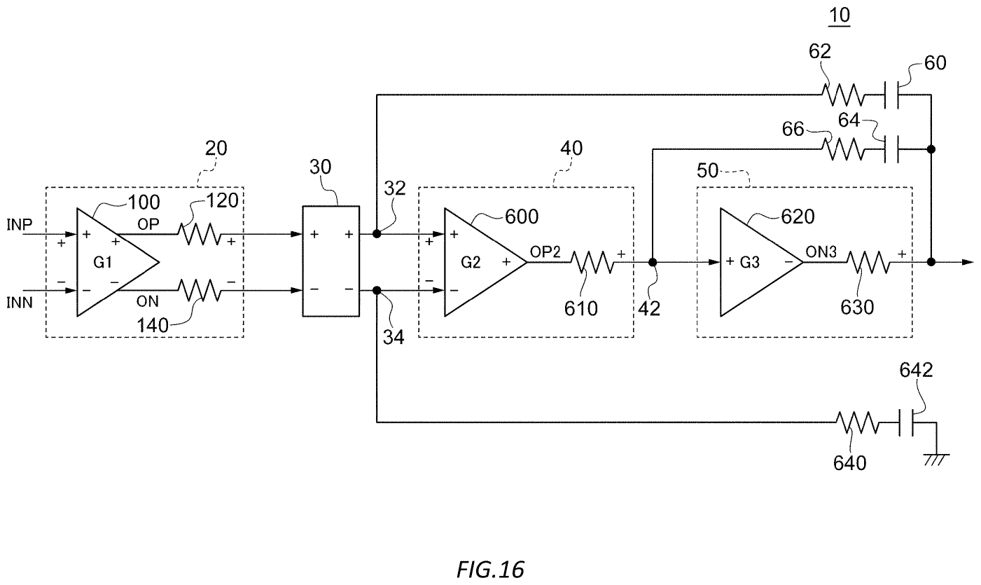

FIG. 16 shows a second exemplary configuration of a differential amplifier 10 of the present embodiment. The differential amplifier 10 of the second exemplary configuration may be similar to that of the first exemplary configuration, except that it has a single output in the second stage amplification circuit 40 and the third stage amplification circuit 50. Similar to the first exemplary configuration, the differential amplifier 10 of the second exemplary configuration includes at least one of the RC filters 30 of the first circuit example to the tenth circuit example.

To the second stage amplification circuit 40, the signal OP, ON output from the first differential amplification circuit 100 are differentially input via the RC filter 30, and the second stage amplification circuit 40 output an amplified signal OP2 as a single output. The second stage amplification circuit 40 includes a second differential amplification circuit 600 and a seventh output resistor 610.

The second differential amplification circuit 600 is connected to a positive output terminal (+) and a negative output terminal (−) of the RC filter 30. The second differential amplification circuit 600 includes a third input terminal (+) and a fourth input terminal (−) to which a first output signal and a second output signal filtered by the RC filter 30 are respectively input, and a third output terminal (+) that outputs a third output signal OP2 according to the first output signal and the second output signal. The second differential amplification circuit 600 amplifies, with a predetermined gain G2 (G2 times), a voltage difference between the third input terminal and the fourth input terminal resulting from the first output signal and the second output signal differentially input and outputs the third output signal OP2 according to the signal level of the amplified voltage difference from the third output terminal as a single output.

The seventh output resistor 610 has one end thereof connected to the third output terminal of the second differential amplification circuit 600 and another end thereof connected to the fifth input terminal of the third amplification circuit 620.

The third stage amplification circuit 50 amplifies the signal output from the second differential amplification circuit 600 and outputs it as a single output. The third stage amplification circuit 50 includes the third amplification circuit 620 and an eighth output resistor 630.

The third amplification circuit 620 is connected to the third output terminal of the second differential amplification circuit 600. The third amplification circuit 620 includes a fifth input terminal (+) to which the third output signal OP2 output from the second differential amplification circuit 600 is input and a fourth output terminal (−) that outputs a fourth output signal ON3 according to the third output signal OP2. The third amplification circuit 620 amplifies a signal level of the third output signal OP2 input with a predetermined gain G3 (G3 times) and outputs the amplified fourth output signal ON3. The eighth output resistor 630 has one end thereof connected to the fourth output terminal of the third amplification circuit 620 and another end thereof connected to an output terminal of the differential amplifier 10.

The third feedback resistor 640 has one end thereof connected to a node 34 between the negative output terminal of the RC filter 30 and the fourth input terminal of the second differential amplification circuit 600 and another end thereof connected to one end of the third feedback capacitor 642. The third feedback capacitor 642 has one end thereof connected to a node 34 between the RC filter 30 and the fourth input terminal of the second differential amplification circuit 600 via the third feedback resistor 640 and another end thereof connected to a reference potential. In the differential amplifier 10 of the present embodiment, the negative fourth input terminal of the second differential amplification circuit 600 is connected to a reference potential via the third feedback resistor 640 and the third feedback capacitor 642.

The differential amplifier 10 of the present embodiment has the RC filter 30 arranged between the output of the first stage amplification circuit 20 and the input of the second stage amplification circuit 40 to generate a first pole, a second pole, and a zero point in an open-loop characteristic of the gain, allowing a stable operation of the differential amplifier 10.

Now, an approach will be described to reduce an increase in die cost when the differential amplifier 10 of the first exemplary configuration or the second exemplary configuration of the present embodiment is implemented in a large scale integrated circuit.

As an example, when the differential amplifier 10 includes the RC filter 30 of the ninth circuit example, the first filter capacitor 404 constitutes the second pole as expressed by Expression 14. Here, when Expression 13 and Expression 14 are compared, it can be seen that the capacitance value C41 of the first feedback capacitor 60 in Expression 13 has an amplified capacitance value by the gain G2 of the second differential amplification circuit 200 or the gain G3 of the third amplification circuit 300, while the capacitance value C271 of the first filter capacitor 404 in Expression 14 constitutes the second pole by itself. Thus, in order to adjust the second pole to be a desired frequency, the capacitance value C271 of the first filter capacitor 404 may become larger than the capacitance value C41, and the die size may become greater when the differential amplifier 10 is implemented in the large scale integrated circuit. Thus, in order to reduce the increase in the die cost, the die size of the filter capacitor that constitutes the RC filter 30 is preferably small.

The breakdown voltage of the capacitor and the capacitance value per unit area are in an inverse proportional relationship. That is, when the breakdown voltage of the capacitor is not required, the die size of the capacitor can be smaller for the same capacitance value. Here, the minimum required breakdown voltage for the first filter capacitor 404 of the RC filter 30 of the differential amplifier 10 is denoted as Vcmax. Vcmax may be equivalent to an amplitude of the signal output from the first stage amplification circuit 20 because the RC filter 30 is arranged between the output of the first stage amplification circuit 20 and the input of the second stage amplification circuit 40. In addition, when the output amplitude required in the output terminal of the differential amplifier 10 is denoted as Vout, Expression 16 below holds because the signal output from the first stage amplification circuit 20 has its amplitude amplified by the gains of the second stage amplification circuit 40 and the third stage amplification circuit 50, and then is output from the output terminal of the differential amplifier 10.

Vcmax=Vout/(G2*G3) (16)

The breakdown voltage required for each of the capacitors constituting the differential amplifier 10 of the first exemplary configuration and the differential amplifier 10 of the second exemplary configuration will be described. For the feedback capacitors having one end thereof connected to the output terminal of the differential amplifier 10, such as the first feedback capacitor 60 and the third feedback capacitor 74 in the differential amplifier 10, the breakdown voltage is preferably at least equal to or greater than the Vout. However, it can be seen from Expression 16 that the required breakdown voltage for the filter capacitors constituting the RC filter 30 may be lower than those of the first feedback capacitor 60 and the third feedback capacitor 74 because G2*G3 is at least approximately several hundred times. Accordingly, the filter capacitor of the RC filter 30 preferably has a lower breakdown voltage compared to the first feedback capacitor 60 and the third feedback capacitor 74 connected to the output terminal of the differential amplifier 10. As a result, this allows a reduction in the implementation size, and thus the increase in die cost can be reduced when the differential amplifier 10 is implemented in the large scale integrated circuit.

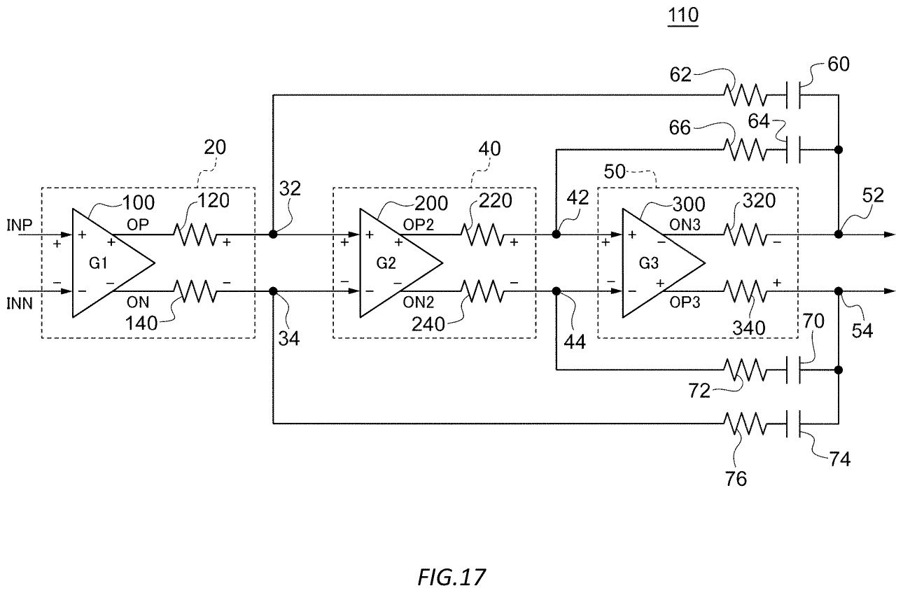

FIG. 17 shows a differential amplifier 110 of a reference example. The differential amplifier 110 of the reference example has a similar configuration to that of the differential amplifier 10 of the first exemplary configuration, except that the first output terminal and the second output terminal of the first differential amplification circuit 100 are directly connected to the second differential amplification circuit 200 via the first output resistor 120 and the second output resistor 140 without including the RC filter 30 between the first differential amplification circuit 100 and the second differential amplification circuit 200.

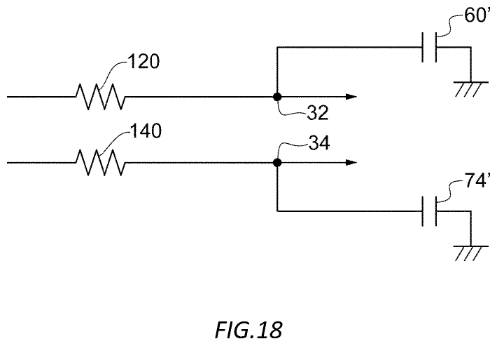

FIG. 18 shows an equivalent circuit of a part of the differential amplifier 110 of the reference example. FIG. 18 shows, as the equivalent circuit, a transmission circuit where the signal amplified by G1 times in the first stage amplification circuit 20 is directly input to the second stage amplification circuit 40. In the equivalent circuit shown in FIG. 18, omission of some elements or resizing of elements has been equivalently performed as well as change of wiring has also been equivalently performed on the transmission circuit of the differential amplifier 110 of the reference example. Note that, in FIG. 18, the first feedback resistor 62 and the third feedback resistor 76 are omitted because they are elements to adjust the phase characteristic of the differential amplifier 110 and also elements that do not contribute to the first pole, the second pole, and the zero point.

The first feedback capacitor 60 has one end thereof connected to the output of the third stage amplification circuit 50 and another end thereof connected to the input of the second stage amplification circuit 40 via the first feedback resistor 62. Accordingly, the first feedback capacitor 60 can be regarded as a capacitor having a capacitance value C41 amplified by the gain G2 of the second stage amplification circuit 40 and the gain G3 of the third stage amplification circuit 50 and having one end thereof connected to a reference potential. Thus, the first feedback capacitor 60′ in FIG. 18 can be equivalently represented as a capacitor with a capacitance of G1*G2*C41 having one end thereof connected to the node 32 and another end thereof connected to a reference potential.

The third feedback capacitor 74 has one end thereof connected to the output of the third stage amplification circuit 50 and another end thereof connected to the input of the second stage amplification circuit 40 via the third feedback resistor 76. Accordingly, the third feedback capacitor 74 can be regarded as a capacitor having a capacitance value C42 amplified by the gain G2 of the second stage amplification circuit 40 and the gain G3 of the third stage amplification circuit 50 and having one end thereof connected to a reference potential. Thus, the third feedback capacitor 74′ in FIG. 18 can be equivalently represented as a capacitor with a capacitance of G1*G2*C42 having one end thereof connected to the node 34 and another end thereof connected to a reference potential.

When a voltage at the first output terminal in the first differential amplification circuit 100 is denoted as +VO, a voltage at the second output terminal is denoted as −VO, a voltage at the node 32 is denoted as +VIN2, and a voltage at the node 34 is denoted as −VIN2, VIN2 is expressed by the transfer function of Expression 17 below. Here, in Expression 17, R11 represents a resistance value of the first output resistor 120, G2 represents a gain of the second differential amplification circuit 200, G3 represents a gain of the third amplification circuit 300, C41 represents a capacitance value of the first feedback capacitor 60, and s represents Laplace operator of Laplace transform.

$$VIN 2 = 1 / ( 1 + s * R 11 * G 2 * G 3 * C 41 ) * VO \qquad ( 17 )$$

(1+s*R11*G2*G3*C41) shown in the denominator of Expression 17 indicates that there is one pole in the open-loop characteristic of the differential amplifier 110, and this pole is the first pole of the differential amplifier 110 in the reference example. The first pole of the differential amplifier 110 of the reference example is calculated by Expression 17 and expressed by Expression 18 below.

$$The first pole = 1 / ( 2 π * R 11 * G 2 * G 3 * C 41 ) \qquad ( 18 )$$

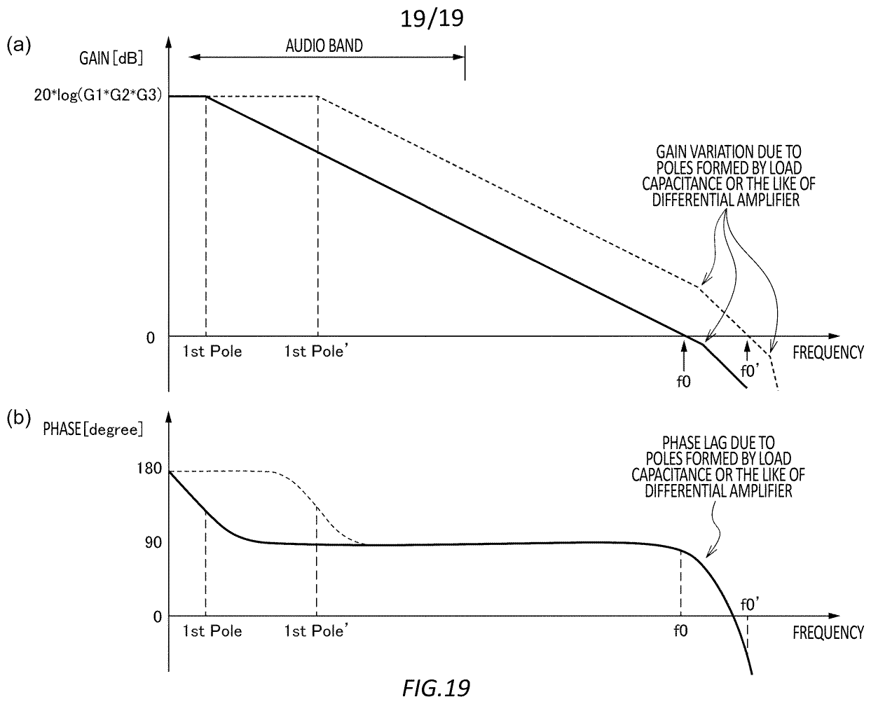

FIG. 19 illustrates a gain and a phase characteristic in the open-loop of the differential amplifier 110 of the reference example. In FIG. 19, (a) shows a relationship between the gain and the frequency of the input signal of the differential amplifier 110 of the reference example, and (b) shows a relationship between the phase of the output signal and the frequency of the input signal of the differential amplifier 110 of the reference example.

In (a) and (b) in FIG. 19, the solid line represents a gain and a phase characteristic in a practical open-loop in which the frequency at the first pole has been adjusted for stable operation of the differential amplifier 110 of the reference example. In FIG. 19, 1st Pole represents the frequency at the first pole and f0 represents a unity gain frequency. In (a) and (b) in FIG. 19, the dotted line represents a gain and a phase characteristic when the capacitance value C41 of the first feedback capacitor 60 is provisionally set to a small value, and 1st Pole′ and f0′ respectively represent the frequency at the first pole and the unity gain frequency in a hypothetical state.

In a frequency range from the frequency zero (DC) to the frequency at the first pole, the gain is equal to G1*G2*G3, which is the DC gain, and when the frequency exceeds the first pole, the gain attenuates at 20 dB/dec, and subsequently the unity gain frequency is reached at which the gain becomes 0 dB. A pole generated due to the load capacitance or the like connected to the output terminal of the differential amplifier 110 generally causes a phase delay exceeding 180 degrees, and thus for the stable operation of the differential amplifier 110, it is necessary to set f0 to a frequency lower than the frequency of the pole generated due to the load capacitance or the like connected to the output terminal of the differential amplifier 110.

As shown by the solid line in FIG. 19, the frequency at the first pole in the open loop of the differential amplifier 110 of the reference example is arranged in the vicinity of the left end of the audio band, and thus it can be seen that the gain in most of the frequency range of the audio band is lower than the DC gain. Thus, it can be seen that if the frequency at the first pole can be provisionally moved to a higher frequency, the gain in the audio band can be improved. Because the frequency at the first pole is expressed by Expression 18, setting the capacitance value C41, for example, to be a smaller value enables the frequency at the first pole to be moved to a higher frequency.

When comparing the gain characteristics of the solid line and the dotted line in FIG. 19, the gain of the dotted line in the audio band is higher than that of the solid line, and thus the audio signal processing with high precision can be expected. However, when the frequency at the first pole is moved from the frequency represented at 1st Pole to the higher frequency represented at 1st Pole′ in order to improve the gain in the audio band, the frequency at f0 also moves in conjunction to the higher frequency represented at f0′. As a result, in the state represented by the dotted line, a phase delay exceeding 180 degrees occurs in a frequency range lower than f0′ as shown in FIG. 19 (b). Accordingly, the differential amplifier 110 of the reference example is in an oscillating state and cannot operate stably, and thus cannot perform the audio signal processing with high precision.

In the differential amplifier 110 of the reference example, the frequency at the first pole is generally automatically determined in order to stably operate the differential amplifier 110 in an actual design situation in which a sudden phase delay is present due to a pole formed by a load capacitance or the like, and thus further improvement of the gain in the audio band is found to be difficult.

While the present invention has been described above by using the embodiments, the technical scope of the present invention is not limited to the scope of the above-described embodiments. It is apparent to persons skilled in the art that various alterations or improvements can be made to the above-described embodiments. It is also apparent from descriptions of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

What is claimed is:

1. A differential amplifier comprising:
a first differential amplification circuit that has a first input terminal to which a first input signal is input, a second input terminal to which a second input signal is input, a first output terminal and a second output terminal which respectively output a first output signal and a second output signal according to the first input signal and the second input signal;
an RC filter that filters the first output signal and the second output signal output from the first output terminal and the second output terminal of the first differential amplification circuit and outputs them;
a second differential amplification circuit that has a third input terminal and a fourth input terminal to which the first output signal and the second output signal filtered by the RC filter are respectively input and a third output terminal which outputs a third output signal according to the first output signal and the second output signal; and
a third amplification circuit that has a fifth input terminal to which the third output signal output from the second differential amplification circuit is input and a fourth output terminal which outputs a fourth output signal according to the third output signal; and
a first feedback capacitor that has one end thereof connected to a node between the RC filter and the third input terminal of the second differential amplification circuit and another end thereof connected to the fourth output terminal of the third amplification circuit, wherein
the RC filter has a first filter section including a first filter capacitor and a first filter resistor connected in series, and a first resistor connected in series between the first output terminal and the third input terminal,
the first filter resistor is configured with an element having an electrical resistance value higher than that of the first resistor, and
the first filter section has one end thereof connected to a node between the first output terminal of the first differential amplification circuit and the first resistor and another end thereof connected to a node between the second output terminal of the first differential amplification circuit and the fourth input terminal of the second differential amplification circuit.

2. The differential amplifier according to claim 1, further comprising:
a second feedback capacitor that has one end thereof connected to a node between the third output terminal of the second differential amplification circuit and the fifth input terminal of the third amplification circuit and another end thereof connected to the fourth output terminal of the third amplification circuit.

3. The differential amplifier according to claim 2, wherein
the RC filter has a second filter section including a second filter capacitor and a second filter resistor connected in series and a second resistor connected in series between the second output terminal and the fourth input terminal,
the second filter resistor is configured with an element having an electrical resistance value higher than that of the second resistor, and
the second filter section has one end thereof connected to a node between the second output terminal of the first differential amplification circuit and the second resistor and another end thereof connected to a node between the first resistor and the third input terminal of the second differential amplification circuit.

4. A differential amplifier comprising:
a first differential amplification circuit that has a first input terminal to which a first input signal is input, a second input terminal to which a second input signal is input, a first output terminal and a second output terminal which respectively output a first output signal and a second output signal according to the first input signal and the second input signal;
an RC filter that filters the first output signal and the second output signal output from the first output terminal and the second output terminal of the first differential amplification circuit and outputs them;
a second differential amplification circuit that has a third input terminal and a fourth input terminal to which the first output signal and the second output signal filtered by the RC filter are respectively input and a third output terminal which outputs a third output signal according to the first output signal and the second output signal; and
a third amplification circuit that has a fifth input terminal to which the third output signal output from the second differential amplification circuit is input and a fourth output terminal which outputs a fourth output signal according to the third output signal, wherein
the RC filter has
a first buffer that has an input thereof connected to the first output terminal of the first differential amplification circuit and an output thereof connected to the third input terminal of the second differential amplification circuit; and
a second buffer that has an input thereof connected to the second output terminal of the first differential amplification circuit and an output thereof connected to the fourth input terminal of the second differential amplification circuit, and
the differential amplifier comprises a first feedback capacitor that has one end thereof connected to a node between the output of the first buffer and the third input terminal of the second differential amplification circuit and another end thereof connected to the fourth output terminal of the third amplification circuit.

5. The differential amplifier according to claim 4, wherein
the RC filter has
a first filter section including a first filter capacitor and a first filter resistor connected in series, and a first resistor connected in series between the first output terminal and the input of the first buffer,
a second filter section including a second filter capacitor and a second filter resistor connected in series, and a second resistor connected in series between the second output terminal and the input of the second buffer,
the first filter resistor is configured with an element having an electrical resistance value higher than that of the first resistor,
the second filter resistor is configured with an element having an electrical resistance value higher than that of the second resistor,
the first filter section has one end thereof connected to a node between the first output terminal of the first differential amplification circuit and the first resistor and another end thereof connected to a node between the second output terminal of the first differential amplification circuit and the input of the second buffer, and
the second filter section has one end thereof connected to a node between the second output terminal of the first differential amplification circuit and the second resistor and another end thereof connected to a node between the first resistor and the input of the first buffer.

6. The differential amplifier according to claim 4, wherein
the RC filter has a filter section that includes:
a first filter resistor having one end thereof connected to a node between the first output terminal of the first differential amplification circuit and the input of the first buffer;
a second filter resistor having one end thereof connected to a node between the second output terminal of the first differential amplification circuit and the input of the second buffer; and
a first filter capacitor and a second filter capacitor that are connected in parallel between another end of the first filter resistor and another end of the second filter resistor.

7. The differential amplifier according to claim 4, wherein
the RC filter has a filter section that includes:
a first filter capacitor having one end thereof connected to a node between the first output terminal of the first differential amplification circuit and the input of the first buffer;
a second filter capacitor having one end thereof connected to a node between the second output terminal of the first differential amplification circuit and the input of the second buffer; and
a filter resistor connected between another end of the first filter capacitor and another end of the second filter capacitor.

8. The differential amplifier according to claim 2, wherein
the third output terminal of the second differential amplification circuit includes
a positive third output terminal and a negative third output terminal that respectively output a third non-inverted output signal and a third inverted output signal according to the first output signal and the second output signal,
the fifth input terminal of the third amplification circuit includes
a positive fifth input terminal to which the third non-inverted output signal is input, and
a negative fifth input terminal to which the third inverted output signal is input,
the fourth output terminal of the third amplification circuit includes
a negative fourth output terminal and a positive fourth output terminal that respectively output a fourth inverted output signal and a fourth non-inverted output signal according to the third non-inverted output signal and the third inverted output signal,
the first feedback capacitor has one end thereof connected to a node between the RC filter and the third input terminal of the second differential amplification circuit and another end thereof connected to the negative fourth output terminal of the third amplification circuit,
the second feedback capacitor has one end thereof connected to a node between the positive third output terminal of the second differential amplification circuit and the positive fifth input terminal of the third amplification circuit and another end thereof connected to the negative fourth output terminal of the third amplification circuit, and
the differential amplifier further comprises:
a third feedback capacitor having one end thereof connected to a node between the RC filter and the fourth input terminal of the second differential amplification circuit and another end thereof connected to the positive fourth output terminal of the third amplification circuit; and
a fourth feedback capacitor having one end thereof connected to a node between the negative third output terminal of the second differential amplification circuit and the negative fifth input terminal of the third amplification circuit and another end thereof connected to the positive fourth output terminal of the third amplification circuit.

9. The differential amplifier according to claim 3, wherein
the third output terminal of the second differential amplification circuit includes
a positive third output terminal and a negative third output terminal that respectively output a third non-inverted output signal and a third inverted output signal according to the first output signal and the second output signal,
the fifth input terminal of the third amplification circuit includes
a positive fifth input terminal to which the third non-inverted output signal is input, and
a negative fifth input terminal to which the third inverted output signal is input,
the fourth output terminal of the third amplification circuit includes
a negative fourth output terminal and a positive fourth output terminal that respectively output a fourth inverted output signal and a fourth non-inverted output signal according to the third non-inverted output signal and the third inverted output signal,
the first feedback capacitor has one end thereof connected to a node between the RC filter and the third input terminal of the second differential amplification circuit and another end thereof connected to the negative fourth output terminal of the third amplification circuit,
the second feedback capacitor has one end thereof connected to a node between the positive third output terminal of the second differential amplification circuit and the positive fifth input terminal of the third amplification circuit and another end thereof connected to the negative fourth output terminal of the third amplification circuit, and
the differential amplifier further comprises:
a third feedback capacitor that has one end thereof connected to a node between the RC filter and the fourth input terminal of the second differential amplification circuit and another end thereof connected to the positive fourth output terminal of the third amplification circuit; and
a fourth feedback capacitor that has one end thereof connected to a node between the negative third output terminal of the second differential amplification circuit and the negative fifth input terminal of the third amplification circuit and another end thereof connected to the positive fourth output terminal of the third amplification circuit.

10. The differential amplifier according to claim 1, further comprising:
a third feedback capacitor having one end thereof connected to a node between the RC filter and the fourth input terminal of the second differential amplification circuit and another end thereof connected to a reference potential.
